(19) United States
(12) Patent Application Publication
(10) Pub. No.: US 2002/0124224 A1
(43) Pub. Date: Sep. 5, 2002

(54) Method and system for matching information rates in turbo coded channels

(76) Inventors: Thomas Keith Blankenship, Streamwood, IL (US); Brian Keith Classon, Palatine, IL (US); Vipul Anil Desai, Palatine, IL (US)

Correspondence Address: MOTOROLA, INC., 1303 EAST ALGONQUIN ROAD, IL01/3RD, SCHAUMBURG, IL, 60196

(21) Appl. No.: 09/969,210

(22) Filed: Oct. 2, 2001

Related U.S. Application Data
(60) Provisional application No. 60/259,058, filed on Dec. 29, 2000.

(51) Int. Cl. H03M 13/00

(52) U.S. Cl. 714/758

(57) ABSTRACT

A method of preparing an information sequence before encoding is provided. An information sequence size of the information sequence is compared to an interleaver size of an interleaver. At least one symbol is added to the information sequence to match the information sequence size to the interleaver size. Systems and programs for preparing an information sequence before encoding are also provided.

### CROSS REFERENCE TO RELATED APPLICATIONS

This application claims the benefit of provisional U.S. patent application No. 60/259,058 filed Dec. 29, 2000, to inventors Blankenship et al. (Attorney Docket No. CR00255M), herein incorporated by reference in its entirety.

### TECHNICAL FIELD OF THE INVENTION

The present invention relates generally to the field of communication systems. In particular, the present invention provides a method of adding symbols to an information stream in order to provide a fixed symbol rate for the encoder of the information stream.

### BACKGROUND OF THE INVENTION

In some communication systems, turbo codes may typically be employed for error correction. Systems that use turbo codes are being standardized to operate over a large number of different information rates. However, in a typical system, there may be a small set of fixed channel rates to accommodate the large number of different information rates. Rate matching may be required when the information rate does not match the channel rate.

In the current approach, the information symbols are first encoded. Depending on the channel rate, the encoded symbols can be punctured and/or repeated so that the result matches the channel rate requirement.

A typical turbo encoder can be comprised of convolutional encoders and interleavers. The interleavers can permute the information block in such a way as to be advantageous for system performance. In general, the interleaver size is equal to the size of the information block, and hence a separate interleaver can be required for each information block (i.e., the size of the information block may correspond to the information rate). To support a large number of information rates, this requirement can result in excessive memory requirements for the interleavers. For example, in the 3GPP1 standard, since the size of an information block can range between 40 and 5114 bits, 5075 different interleavers are required.

To reduce the required number of interleavers, a family of interleavers may be specified which can be pruned to appropriate sizes while maintaining desirable properties of interleavers. For example, the 3GPP1 standard specifies a family of 158 interleavers. Although this reduces the number of interleavers, excessive memory may still be required. For example, an entire family of interleavers may be precomputed and stored but such storage requires additional memory. Alternatively, appropriate interleavers may be generated and stored as needed. While this option reduces memory requirements, the computational complexity increases since a different interleaver may be required between successive information blocks.

Another option would be to develop a single interleaver design algorithm that can produce appropriate interleavers for a large span of information block sizes. However, such an interleaver design remains elusive to turbo coding researchers.

It would be desirable therefore to provide a method of matching the rate at which information is transmitted to a channel that overcomes the above.

### BRIEF DESCRIPTION OF THE DRAWINGS

FIG. 1 is a flow diagram of one embodiment of a method for modifying an information burst in accordance with the present invention;

FIG. 2 is a schematic representation of an information burst that has been modified in accordance with one embodiment of the present invention;

FIG. 3 is a schematic representation of an information burst that has been modified in accordance with the prior art;

FIG. 4 is a flow diagram of one embodiment of a method for modifying an information burst in accordance with the present invention;

FIG. 5 is a schematic representation of one embodiment of a turbo decoding device that may be used in accordance with the present invention;

FIG. 6 is a schematic representation of an information burst that has been modified in accordance with a second embodiment of the present invention;

FIG. 7 is a flow diagram of a second embodiment of a method for modifying an information burst in accordance with the present invention;

FIG. 8 is a schematic representation of a second embodiment of a turbo decoding device that may be used in accordance with the present invention;

FIG. 9 is a schematic representation of an information burst that has been modified in accordance with one embodiment of the present invention; and

FIG. 10 is a schematic representation of an information burst that has been modified in accordance with one embodiment of the present invention.

### DETAILED DESCRIPTION OF THE PRESENTLY PREFERRED EMBODIMENTS

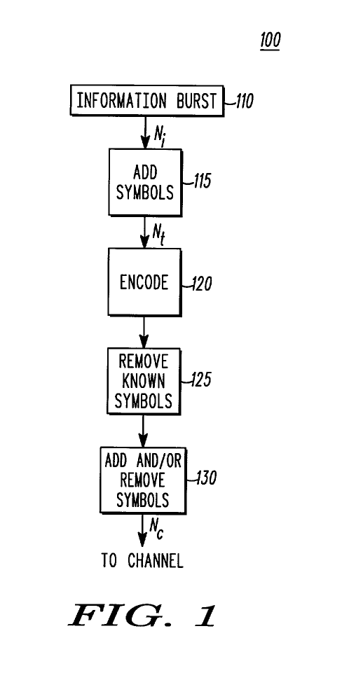

FIG. 1 shows a flow diagram of one embodiment of a method for modifying an information burst in accordance with the present invention at 100. An information burst 110 having a frame size of Nᵢ symbols may be modified and encoded to match a channel frame size N_{c}. The term “burst” appearing herein may refer to a short or isolated transmission, a portion of a longer transmission, a portion of a continuous transmission, a portion of a semi-continuous transmission, a time-limited transmission, a bandwidth-limited transmission, or any combination thereof. Information burst 110 may include coded or uncoded source information. Information burst 110 comprises any suitable number of information symbols. Information burst 110 may be transmitted from any suitable transmitting device to any suitable receiving device. For example, information burst 110 may be transmitted from a base station to a wireless cellular device. Alternatively, a cellular device may transmit information burst 110 to a base station.

At block 115, symbols may be added to information burst 110 to meet an encoder input frame size Nₜ requirement. In some systems, such as those employing adaptive modulation, there may be a plurality of encoder input frame size requirements. There may be many embodiments of the symbol-adding step described at block 115, only some of which are presented in the succeeding figures. Additionally, block 115 may include processing to determine the added symbols.

At block 120, the modified information burst is encoded by an encoder that accepts input frames of size Nₜ symbols. In the embodiment where the encoder is a turbo encoder, Nₜ may equal the size of the turbo interleaver. In some systems, such as those employing adaptive modulation, since there may be a plurality of encoder input frame sizes, there may thus be a plurality of turbo interleavers.

In some cases, when known symbols are added at block 115, due to the deterministic mapping of encoder input to encoder output, known symbols may therefore appear at the encoder output. For example, if the encoder is systematic, one component of the encoder output is an exact replica of the encoder input. To avoid transmitting known information, known symbols may be removed at block 125.

Finally, to match an expected channel frame size requirement, N_{c}, at block 130 symbols are added and/or removed. In some embodiments, such addition and/or removal of symbols is done in a manner that assists the receiver in decoding or in a manner that otherwise enhances system performance. For example, the addition of symbols may be accomplished by repeating one or more symbols one or more times in order to effectively increase the energy of these symbols for transmission over the channel.

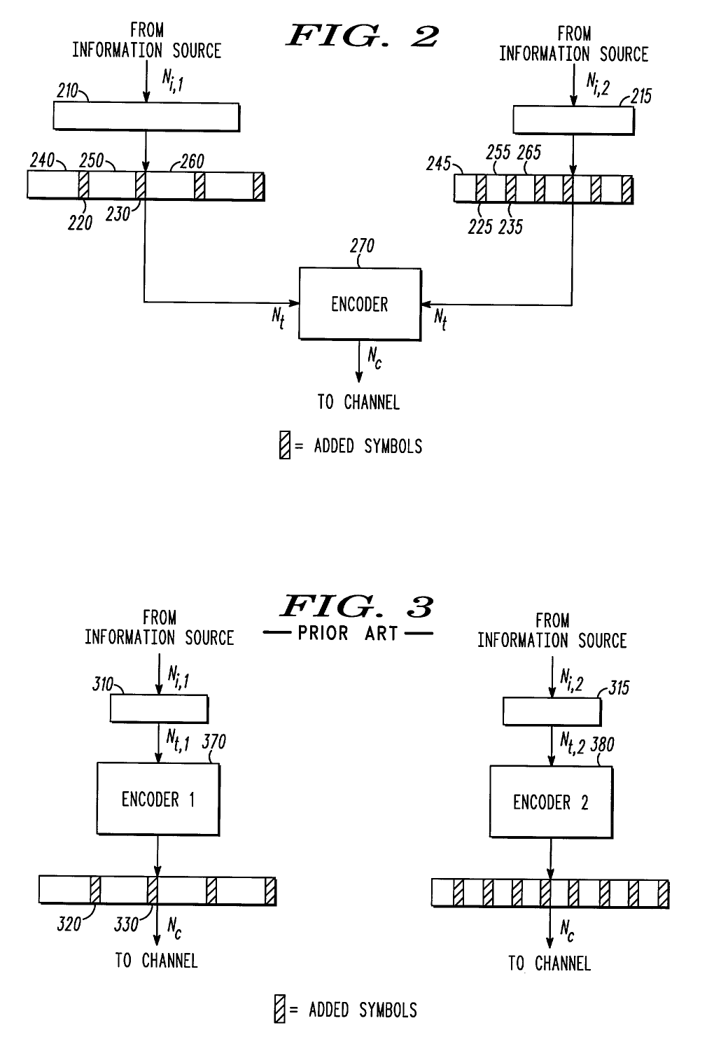

FIG. 2 shows a schematic representation of an information burst of original size N_{i,1} symbols at 210. FIG. 2 also shows a schematic representation of a second information burst of a different original size N_{i,2} symbols at 215.

As seen in FIG. 2, information burst 210 may be modified in accordance with one embodiment of the present invention. The encoder 270, which receives information burst 210, may only encode blocks having code block size Nₜ. The code block size Nₜ may be chosen so that the encoded information block size may match the channel block size N_{c} because the number of encoded symbols may be different than the number of input symbols in general. In the example shown in FIG. 2, N_{i,1} may not be the same as Nₜ. Thus, in accordance with the present invention, information burst 210 may be modified to match Nₜ in size. As seen in FIG. 2, this is accomplished by placing one or more inserts 220, 230, each consisting of one or more symbols, between burst portions 240, 250, 260 before information burst 210 is sent to encoder 270. In the embodiment of FIG. 2, inserts 220 and 230 may have different sizes. In one embodiment, the total number of symbols Nₛ that comprise the inserts may be determined by the formula

Nₛ=Nₜ−N_{i,1}.

Inserts 220, 230 may be any suitable number and combination of symbols. In this example, information burst 210 has four inserts, including inserts 220 and 230. However the number of symbols, combination of symbols and number of inserts inserted may be any suitable number. In some embodiments of the invention the number of inserted symbols, Nₛ may be related to the code block size and the information burst size.

This may be further illustrated with reference to information burst 215. In the embodiment shown in FIG. 2, information burst 215 has a different original size than information burst 210. Information burst 215 may also be modified in accordance with the embodiment of the invention described above. Thus, inserts 225 and 235 are placed between burst portions 245, 255, 265. In this example, information burst 215 has six inserts, including inserts 225 and 235.

Inserts 220, 230, 225, 235 may convey information or may simply serve to modify information burst 210, 215 so that information burst 210, 215 matches the expected encoder code block size Nₜ. For example, in one embodiment of the invention, inserts 220, 230 comprise one or more zero symbols. Similarly, in information burst 215, inserts 225, 235 may comprise one or more zero symbols. In another embodiment of the invention, the value and position of the inserted symbols, (i.e., the value and position of inserts 220, 230, 225, 235) may be chosen to maximize decoding or error detection processing performance. Furthermore, if the encoder is systematic, the inserted symbols (e.g., inserts 220, 230, 225, 235) may be present at the output of the encoder. Consequently, the inserts 220, 230, 225, 235, et al., and possibly portions of the parity streams, may comprise known symbols. This may be exploited to improve decoder performance.

As seen in FIG. 2, the method of the present invention allows information bursts 210 and 215 to use the same encoder 270. Although the present invention may have certain advantages for any type of encoder, the present invention is especially advantageous when the encoder is a turbo encoder. This is because a turbo encoder comprises an interleaver that has the same size as the code block size. Implementation of the interleaver requires memory and/or expenditure of computational cycles. Systems with turbo encoders that are designed to support multiple code block sizes are liable to require excessive memory or computational cycles as a result.

This may be seen in comparison to the prior art method show in FIG. 3. FIG. 3, shows a schematic representation of an information burst 310 having size N_{i,1}. An information burst of a different size N_{i,2} is shown at 315. Because no symbols are added before encoding, two different code block sizes result: N_{t,1} and N_{t,2}. Thus, two different encoders 370, 380 are generally be used. For example, if turbo coding is used, then encoders 370, 380 would have two different interleavers, and extra memory and/or computational cycles would be required to implement these two different interleavers. In contrast, in the present invention, symbols may be added before encoding to achieve a single code block size Nₜ, as shown in FIG. 2. In the embodiment of FIG. 2, since a single code block size is achieved, a single encoder may be used. If the encoder is a turbo encoder, then a single interleaver may thus be required. Use of a single interleaver in such circumstances may generally require less memory and/or computational cycles to implement than systems requiring multiple interleavers.

However, in the prior art method of FIG. 3, in order to achieve the channel block size N_{c,} one or more inserts 320, 330 may be added to the encoded blocks (post-encoding). In contrast, the information burst 210, 215 of FIG. 2 may be modified before encoding (pre-encoding), and the code block size Nₜ may be chosen so that the encoded block size matches the channel block size N_{c}.

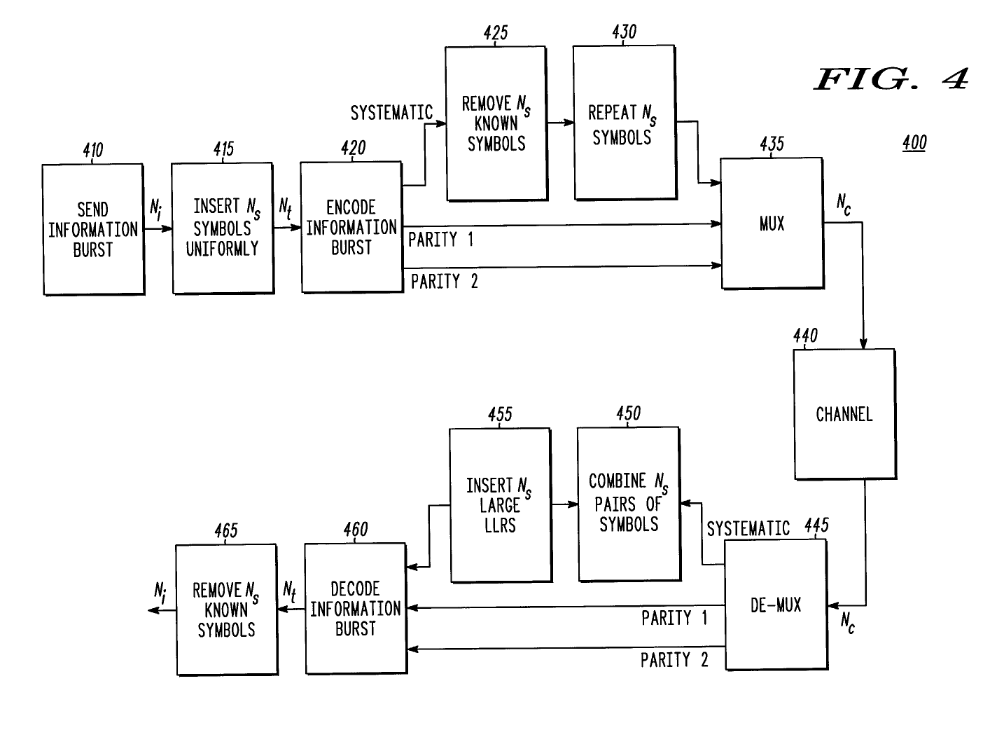

FIG. 4 shows a flow diagram of one embodiment of a method for modifying an information burst in accordance with the present invention at 400. At block 410, an information burst may be sent from an information source as described above. This information burst may be, for example, information burst 210, 215. At block 415, symbols may be inserted into the information burst. In one embodiment of the invention, the symbols are inserted uniformly. The number of symbols inserted is determined as described in FIG. 2 above, depending, for example, on the code block size. In one embodiment of the invention, one or more zero symbols are inserted uniformly using the following uniform insertion algorithm:

C₀ = C₁ = C₂ = D = 0;
F = floor( Nₜ / Nᵢ );
N = Nₜ − F * N₁;
if ( N == 0 )
{

F = F − 1;
N = Nᵢ;

}
while( C₀ < Nᵢ )
{

output[D] = input[C₀];
D = D + 1;
i = 0;
while ( i < F − 1 )
{

output[D] = 0;
D = D + 1;
i = i + 1;

}
if ( C₁ ≧ C₂ )
{

output [D] = 0;
D = D + 1;
C₂ = C₂ + N₁;

}
C₁ = C₁ + N;
C₀ = C₀ + 1;

}

where C₀, C₁, C₂, D, and i are counters, F and N are defined by the algorithm, input[i] is the i-th input symbol, and outputs is the j-th output symbol.

In one embodiment of the invention, where the encoder is a turbo encoder, given an information block of size Nᵢ and a interleaver of size of Nₜ, Nₛ zero symbols may be inserted into the information burst where Nₛ=Nₜ−Nᵢ. These symbols may be inserted uniformly in one embodiment of the invention. The information burst is now appropriately sized to enter the turbo encoder. For example, the information burst may now have the size matching the interleaver, Nₜ.

At block 420, the information burst may be encoded. In the embodiment shown in FIG. 4 a turbo encoder is used. Typically, the output of the turbo encoder comprises a systematic stream and a parity stream. The output of the encoder may comprise, for example, a stream of symbols, including the information burst 100. Since the systematic stream of the turbo encoder comprises the information burst, it contains the Nₛ inserted symbols. In one embodiment of the invention, these symbols may be removed (as seen at block 425). This may be done because it may not be necessary to transmit known information. The symbols removed at block 425 serve to represent the actual information burst but may not actually be part of the information burst 100. The step described at block 425 may occur if the size of the information burst and the insertion algorithm are known to the decoder.

If symbols have been removed at block 425, in order to match the channel block size, some symbols may have to be added. In the embodiment of FIG. 4, a balanced number of symbols into the mux is desired, which is accomplished at block 430 by repeating Nₛ symbols of the systematic stream. At block 435, the encoded symbols enter the mux, which combines the symbols in a manner suitable for transmission over the channel at block 440.

FIG. 4 also shows the receiver processing that may be used in accordance with the present invention. At block 445, the received symbols may be separated into component streams by the de-mux operation. Since before transmission, Nₛ symbols of the systematic stream were repeated (block 430), at block 450 the Nₛ pairs of received repeated symbols may be combined. In one embodiment of the invention, the data from the channel represent log-likelihood ratios (LLRs). In such an embodiment, maximal ratio combining of the Nₛ pairs of repeated symbols is accomplished by adding the two LLRs corresponding to each repeated symbol (as seen at block 450). The Nₛ slots vacated by the combining operation may be designated as zero symbols to recover the transmitted symbol. In the embodiment where the data from the channel represent LLRs, this is accomplished by inserting LLRs of large magnitude into the slots known to contain zero symbols, as seen in block 455. At block 460, the received data may be decoded. In one embodiment of the invention, this may be accomplished with a turbo decoder in accordance with the present invention as further described below. After the data are decoded, at block 465 the Nₛ known symbols may be removed.

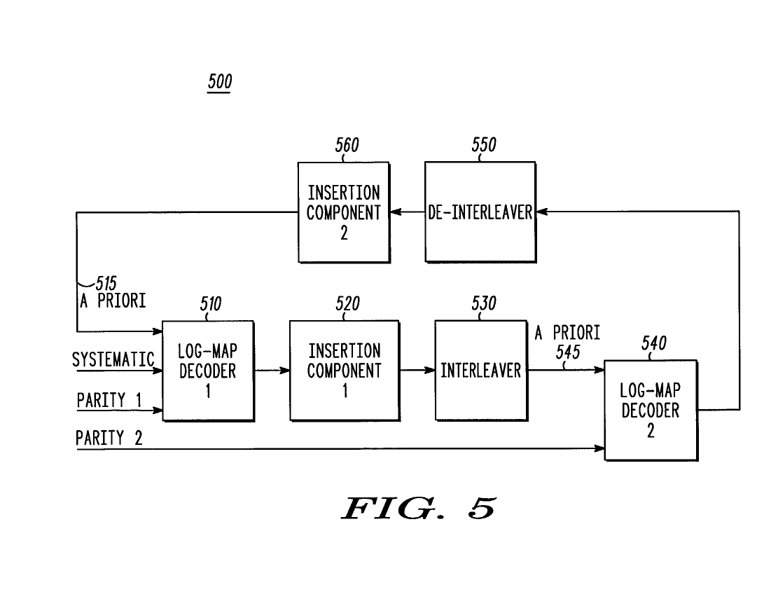

FIG. 5 shows a schematic representation of a turbo decoding device in accordance with the present invention at 500. Turbo decoding device 500 may include at least one log-MAP decoder 510. In the embodiment of FIG. 5, turbo decoding device 500 also includes a second log-MAP decoder 540. Turbo decoding device 500 may also include an interleaver 530 and a de-interleaver 550. Turbo decoding device 500 may also include at least one insertion component 520. In the embodiment of FIG. 5, turbo decoding device 500 also contains a second insertion component 560. In one embodiment of the present invention, insertion components 520, 560 may serve to insert large-magnitude LLRs at locations of known symbols. Thus, at 515 and 545, the soft information exchanged between the constituent decoders manifests a priori knowledge about some of the symbols. This a priori knowledge may be manifested, for example, prior to a pass through decoder 510 (as indicated at 515) and/or prior to a pass through decoder 540 (as indicated at 545).

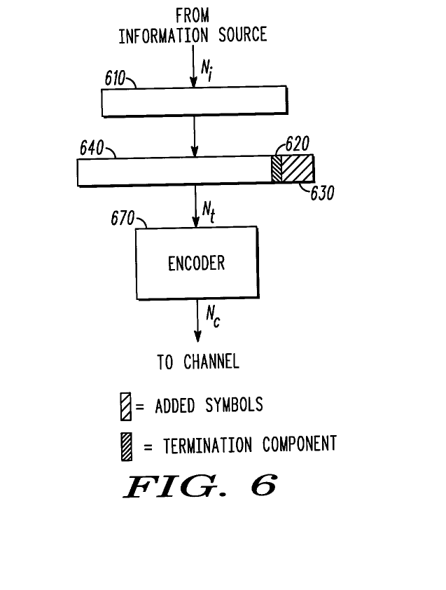

FIG. 6 shows a schematic representation of an information burst that has been modified in accordance with a second embodiment of the present invention at 610. Information burst 610 may comprise any suitable number of information symbols. In the embodiment of FIG. 6, information burst 610 has a size of Nᵢ. The encoder that encodes information burst 610 may expect a block of size Nₜ, which may be chosen so that the encoded information block size may match the channel block size N_{c}. For example, the encoder may be a turbo encoder, in which case Nₜ equals the size of the interleaver. In the example shown in FIG. 6, Nᵢ may not be the same as Nₜ. Thus, in accordance with the present invention, information burst 610 may be modified to match Nₜin size. As seen in FIG. 6, the input into the encoder 670 may comprise information burst 610, a termination component 620, and an insert 630 comprised of at least one symbol. The termination component 620 may be, for example, a sequence determined by processing a portion of information burst 610. In one embodiment of the invention where the encoder 670 is a turbo encoder, an Nᵢ-symbol information burst may be processed to determine a termination component 620 comprised of m symbols that terminates a constituent encoder. In this example, the termination component 620 may place the constituent encoder in a known state, such as the zero state. In one embodiment of the invention, the number of symbols Nₛ that comprise insert 630 may be determined by the formula

Nₛ=Nₜ−Nᵢ−m.

The number of inserted symbols, Nₛ may be related to the code block size and the information burst size.

Termination component 620 and insert 630 may convey information or may simply serve to modify information burst 610 so that information burst 610 matches the expected encoder code block size Nₜ. For example, in one embodiment of the invention, insert 630 may comprise one or more zero symbols. In another embodiment of the invention, the values and positions of termination component 620 and/or insert 630 may be chosen to maximize decoding or error detection performance. Furthermore, if the encoder is systematic, insert 630 may be present at the output of the encoder. Consequently, insert 630, and possibly portions of the parity streams, may comprise known symbols.

FIG. 7 shows a flow diagram of a second embodiment for modifying an information burst in accordance with the present invention at 700. At block 710, an information burst may be sent. At block 715, symbols may be inserted into the information burst. In the present embodiment of the invention where the encoder is a turbo encoder with memory-m constituent encoders an Nᵢ-symbol information block may be processed to determined the m-symbol sequence that will terminate the first constituent encoder at block 720. This m-symbol sequence, followed by Nₛ=Nₜ−Nᵢ−m symbols, may be appended to the information stream, and the terminated, symbol-padded information stream may be passed to the encoder. At block 720, the information burst may be encoded. In the embodiment shown in FIG. 7, there are three streams of encoding shown—a systematic stream, a parity 1 stream and a parity 2 stream. Both the systematic and parity 1 output streams from encoder 1 may contain a tail of Nₛ known symbols. To avoid transmitting known information, those symbols may be removed at blocks 725, 735. The slots vacated by the removal of these symbols may be filled by repeating one or more the systematic and parity 1 symbols as shown in blocks 727 and 737. When the systematic and parity 1 symbols are repeated a balanced input may be provided to the mux at block 740. The steps described at blocks 725, 735, 727, 737 may occur provided that the size of the information burst and the repetition algorithm are known to the receiver. At block 740, the information burst enters the mux, where the streams may be combined in a manner suitable for transmission. The burst may be transmitted over the channel at block 750.

FIG. 7 also shows the receiver processing that may be used in accordance with the present invention. In one embodiment of the invention, the receiver processing described in FIG. 4 may be applied. However, because the transmitter introduces repeated symbols in both the systematic and parity 1 streams at block 720, the decoder may exploit that knowledge to improve system performance. Thus, at blocks 760, 765, Nₛ pairs of symbols may be combined. At block 770, the received information burst may be decoded. This may be done, for example, with a turbo decoder. At block 780, the known Nₛ symbols may be removed. The known symbols may be removed in any suitable manner known in the art.

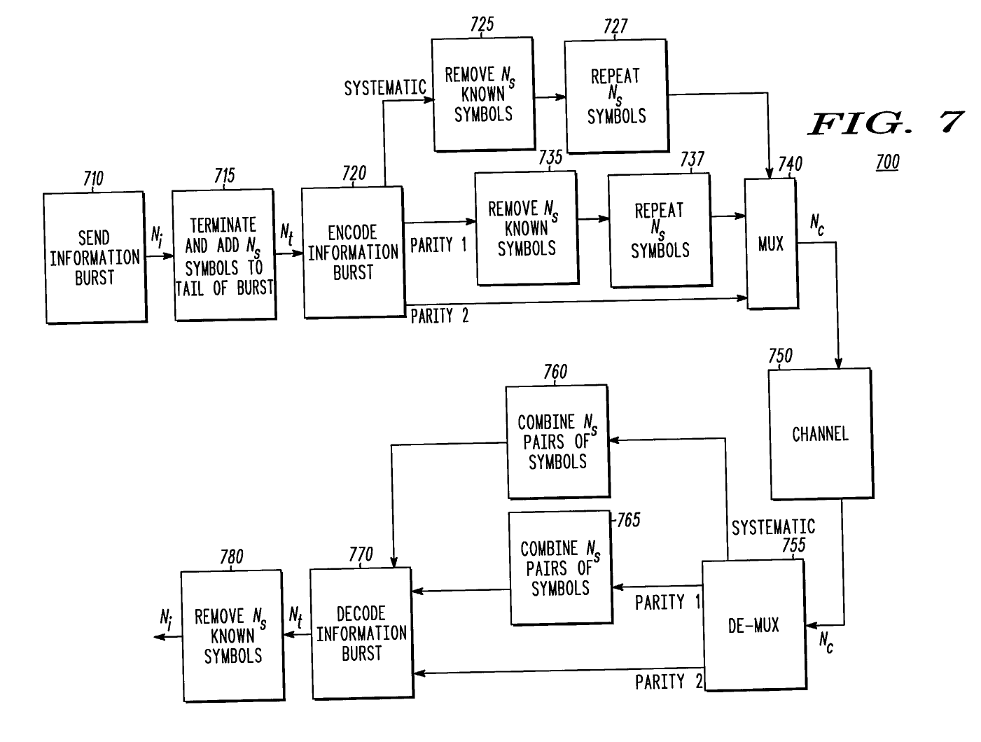

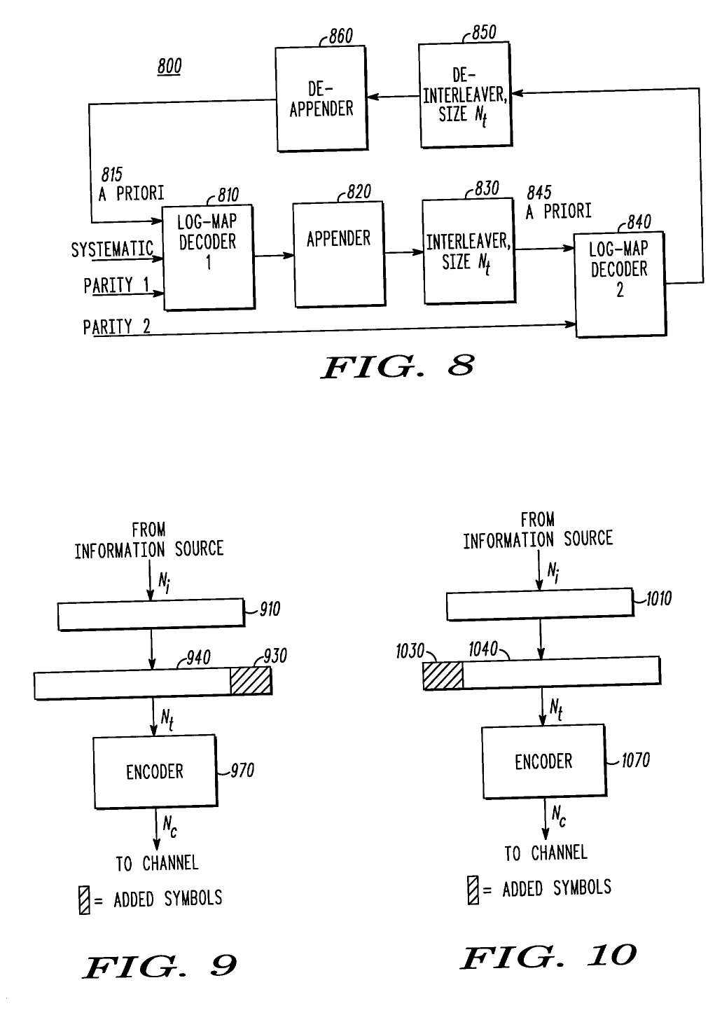

FIG. 8 shows a schematic representation of a second embodiment of a turbo decoding device that may be used in accordance with the present invention at 800. Turbo decoding device 800 may include at least one log-MAP decoder 810. In the embodiment of FIG. 8, the turbo decoding device also includes a second log-MAP decoder 840. Turbo decoding device 800 may also include at least one appender 820. In one embodiment of the invention, appender 820 may serve to insert large LLRs at the tail of the information passed between constituent decoder 810 and constituent decoder 840. Meanwhile, turbo decoding device 800 may also include at least one de-appender 860. In one embodiment of the invention, de-appender 860 may serve to remove large LLRs from the tail of the information passed between constituent decoder 840 and constituent decoder 810. Turbo decoding device 800 may also include an interleaver 830 and a de-interleaver 850. This embodiment of a turbo decoding structure stems from the presently discussed embodiment of the invention, in which the first constituent decoder may operate on only Nᵢ received symbols while the second decoder may operate on Nₜ received symbols. To ensure that the second constituent decoder uses the a priori knowledge that some of the symbols are known, large-magnitude LLRs may be introduced for those symbols. Thus, at 815 and 845 the soft information exchanged between the decoders manifests a priori knowledge about some of the symbols. This a priori knowledge may be manifested, for example, prior to a pass through decoder 810 (as indicated at 815) and/or prior to a pass through decoder 840 (as indicated at 845).

FIG. 9 shows a schematic representation of an information burst that has been modified in accordance with the present invention at 910. Information burst 910 may comprise any suitable number of information symbols. In the embodiment of FIG. 9, information burst 910 has a size of Nᵢ. The encoder that encodes information burst 910 may expect a block of size Nₜ, which may be chosen so that the encoded information block size may match the channel block size N_{c}. For example, the encoder may be a turbo encoder, in which case Nₜ equals the size of the interleaver. In the example shown in FIG. 9, Nᵢ may not be the same as Nₜ. Thus, in accordance with the present invention, information burst 910 may be modified to match Nₜ in size. As seen in FIG. 9, the input into the encoder 970 may comprise information burst 940 and an insert 930 comprised of at least one symbol. In one embodiment of the invention, the number of symbols Nₛ that comprise insert 930 may be determined by the formula

Nₛ=Nₜ−Nᵢ.

The number of inserted symbols, Nₛ may be related to the code block size and the information burst size.

Insert 930 may convey information or may simply serve to modify information burst 910 so that information burst 910 matches the expected encoder code block size Nₜ. For example, in one embodiment of the invention, insert 930 may comprise one or more zero symbols. In another embodiment of the invention, the values and positions of insert 930 may be chosen to maximize decoding or error detection performance. Furthermore, if the encoder is systematic, insert 930 may be present at the output of the encoder. Consequently, insert 930 and possibly portions of the parity streams may comprise known symbols.

FIG. 10 shows a schematic representation of an information burst that has been modified in accordance with the present invention at 1010. Information burst 1010 may comprise any suitable number of information symbols. In the embodiment of FIG. 10, information burst 1010 has a size of Nᵢ. The encoder that encodes information burst 1010 may expect a block of size Nₜ, which may be chosen so that the encoded information block size may match the channel block size N_{c}. For example, the encoder may be a turbo encoder, in which case Nₜ equals the size of the interleaver. In the example shown in FIG. 10, Nᵢ may not be the same as Nₜ. Thus, in accordance with the present invention, information burst 1010 may be modified to match Nₜ in size. As seen in FIG. 10, the input into the encoder 1070 may comprise information burst 1040 and an insert 1030 comprised of at least one symbol. In one embodiment of the invention, the number of symbols Nₛ that comprise insert 1030 may be determined by the formula

Nₛ=Nₜ−Nᵢ.

The number of inserted symbols, Nₛ may be related to the code block size and the information burst size.

Insert 1030 may convey information or may simply serve to modify information burst 1010 so that information burst 1010 matches the expected encoder code block size Nₜ. For example, in one embodiment of the invention, insert 1030 may comprise one or more zero symbols. In another embodiment of the invention, the values and positions of insert 1030 may be chosen to maximize decoding or error detection performance. Furthermore, if the encoder is systematic, insert 1030 may be present at the output of the encoder. Consequently, insert 1030, and possibly portions of the parity streams, may comprise known symbols.

While specific embodiments of the present invention have been shown and described, it will be apparent to those skilled in the art that the disclosed invention may be modified in numerous ways and may assume many embodiments other than those specifically set out and described above. Accordingly, the scope of the invention is indicated in the appended claims, and all changes that come within the meaning and range of equivalents are intended to be embraced therein.

1. A method of preparing an information sequence before encoding, comprising:
comparing an information sequence size of the information sequence to an interleaver size of an interleaver; and
adding at least one symbol to the information sequence to match the information sequence size to the interleaver size.

2. The method of claim 1, further comprising:
determining the information sequence size.

3. The method of claim 1, further comprising:
determining the interleaver size.

4. The method of claim 1, further comprising:
computing a value of the at least one symbol from the information sequence size and the interleaver size.

5. The method of claim 1 wherein the at least one symbol is a plurality of symbols.

6. The method of claim 5, further comprising:
distributing the plurality of symbols within the information sequence.

7. The method of claim 5, further comprising distributing the plurality of symbols uniformly within the information sequence.

8. The method of claim 1, further comprising:
inserting the at least one symbol at an end of the information sequence.

9. The method of claim 8 wherein the end is at a start of the information sequence.

10. The method of claim 8 wherein the end is after the information sequence.

11. The method of claim 1, further comprising:
inserting a termination component before the at least one symbol is inserted.

12. The method of claim 11, further comprising:
processing a portion of the information sequence to determine the termination component.

13. The method of claim 1, further comprising:
encoding the information sequence to produce an encoded stream; and
removing the at least one symbol from the encoded stream.

14. A turbo decoding apparatus, comprising:
at least one interleaver; and
at least one insertion means for inserting at least one symbol into the information sequence until the information sequence matches the interleaver in size.

15. The apparatus of claim 14 wherein the at least one symbol is a plurality of symbols.

16. The apparatus of claim 14, further comprising:
means for determining a value of the plurality of symbols from a size of the information sequence and a size of the interleaver.

17. The apparatus of claim 14, further comprising:
means for distributing a termination component within the information sequence before the at least one symbol is inserted.

18. The apparatus of claim 17, further comprising:
means for processing a portion of the information sequence to determine the termination component.

19. Computer program product in a computer usable medium for preparing an information sequence before encoding, comprising:
computer program code that compares an information sequence size of the information sequence to an interleaver size of an interleaver; and
computer program code that adds at least one symbol to the information sequence to match the information sequence size to the interleaver size.

20. The program of claim 19, further comprising:
computer program code that determines the information sequence size.

21. The program of claim 19, further comprising:
computer program code that determines the interleaver size.

22. The program of claim 19, further comprising:
computer program code that computes a value of the at least one symbol from the information sequence size and the interleaver size.

23. The program of claim 19, wherein the at least one symbol is a plurality of symbols, further comprising:
computer program code that distributes the plurality of symbols within the information sequence.

24. The program of claim 19, further comprising:
computer program code that inserts the at least one symbol at an end of the information sequence.

25. The program of claim 19, further comprising:
computer program code that inserts a termination component before the at least one symbol is inserted.

26. The program of claim 25, further comprising:
computer program code that processes a portion of the information sequence to determine the termination component.

27. The program of claim 19, further comprising:
computer program code that encodes the information sequence to produce an encoded stream; and
computer program code that removes the at least one symbol from the encoded stream.

28. A turbo encoding system, comprising:
means for encoding an information sequence to produce an encoded stream;
means for comparing an information sequence size of the information sequence to an interleaver size of an interleaver; and
means for adding at least one symbol to the information sequence to match the information sequence size to the interleaver size.

29. The system of claim 28, further comprising:
means for determining the information sequence size.

30. The system of claim 28, further comprising:
means for determining the interleaver size.

31. The system of claim 28, further comprising:
means for computing a value of the at least one symbol from the information sequence size and the interleaver size.

32. The system of claim 28, wherein the at least one symbol is a plurality of symbols, further comprising:
means for distributing the plurality of symbols within the information sequence.

33. The system of claim 28, further comprising:
means for inserting the at least one symbol at an end of the information sequence.

34. The system of claim 28, further comprising:
means for inserting a termination component before the at least one symbol is inserted.

35. The system of claim 34, further comprising:
means for processing a portion of the information sequence to determine the termination component.

36. The system of claim 28, further comprising:
means for removing the at least one symbol from the encoded stream.
